(19) United States
(12) Patent Application Publication
(10) Pub. No.: US 2009/0028278 A1
(43) Pub. Date: Jan. 29, 2009

(54) METHOD AND DEVICE FOR REDUCING SURROUNDING COUPLING NOISE

(76) Inventor: Qingquan Shi, Shenzhen (CN)

Correspondence Address: BRINKS HOFER GILSON & LIONE, P.O. BOX 10395, CHICAGO, IL, 60610, US

(21) Appl. No.: 12/237,717

(22) Filed: Sep. 25, 2008

Related U.S. Application Data
(63) Continuation of application No. PCT/CN2007/000091, filed on Jan. 10, 2007.

(30) Foreign Application Priority Data
Mar. 29, 2006 (CN) 200610066806.6

(51) Int. Cl. H03D 1/04

(52) U.S. Cl. 375/346; 455/63.1

(57) ABSTRACT

A method and device for reducing a surrounding coupling noise are disclosed. The method and device include receiving a signal from a receiving end of a line to be processed and obtaining a reference noise signal; determining a weight coefficient for adjusting the reference noise signal; and filtering the reference noise signal with a transfer function configured by the determined weight coefficient, superposing the filtered signal with the signal received by the receiving end of the line to be processed, and outputting the superposed signal.

### CROSS-REFERENCE TO RELATED APPLICATIONS

This is a continuation of PCT application No. PCT/CN2007/000091, filed Jan. 10, 2007, titled “Method and device for reducing surrounding coupling noise”, which claims the priority of Chinese patent application No. 200610066806.6, filed Mar. 29, 2006, the contents of both of which are incorporated herein in their entirety by reference.

### TECHNICAL FIELD

The present embodiments relates to the field of communication technologies, and in particular to a method and device for reducing surrounding coupling noise.

### BACKGROUND

Digital Subscriber Line (DSL) technology is a high speed transmission technology for transmitting data by using a twisted-pair lines for telephone, such as Unshielded Twist Pair (UTP), which includes Asymmetrical Digital Subscriber Line (ADSL), Very-high-bit-rate Digital Subscriber Line (VDSL), Integrated Services Digital Network (ISDN) based ISDN Digital Subscriber Line (IDSL) and Single-pair High-bit-rate Digital Subscriber Line (SHDSL), etc.

In various Digital Subscriber Line (xDSL) technologies, in addition to the DSL using baseband transmission, such as IDSL and SHDSL, the DSL using pass-band transmission allows the DSL and Plain Old Telephone Service (POTS) to coexist on the same twisted-pair lines by using frequency division multiplexing technology, where the DSL occupies the high frequency band and the POTS occupies the baseband part under 4 KHz, and a POTS signal and a DSL signal are split or merged through a splitter/integrator. The xDSL using pass-band transmission conducts modulation and demodulation by using Discrete Multi-Tone Modulation (DMT) technology. A system providing for a multiplexing DSL access is called a DSL Access Multiplexer (DSLAM), a schematic diagram of whose system connection relation is shown in FIG. 1. A DSLAM 120 includes transceiver unit 121 and a splitter/integrator 122. In an uplink direction, the transceiver unit 121 receives a DSL signal from a computer 110, amplifies the received signal and transmits the amplified DSL signal to the splitter/integrator 122. The splitter/integrator 122 integrates the DSL signal from the transceiver unit 121 and a POTS signal from a telephone terminal 130. The integrated signal is received by a splitter/integrator 151 in a DSLAM 150 of a partner terminal through the transmission of a multiplexing UTP 140. The splitter/integrator 151 splits the received signals in which the POTS signal is transmitted to a Public Switched Telephone Network (PSTN) 160 and the DSL signal is transmitted to a transceiver unit 152 of the DSLAM 150. The transceiver unit 152 subsequently amplifies the received signal and transmits it to a Network Management System (NMS) 170. In a downlink direction of the signal, the signal is transmitted in an order reverse to the above.

In the xDSL technology, a UTP is used as a transmission channel, and its non-distortion channel capacity must satisfy Shannon's channel capacity formula:

$$C = B \times {log}_{2} ( 1 + \frac{S}{N} ) \qquad ( 1 )$$

where, C is a channel capacity, B is a signal bandwidth, S is a signal, and N is a noise. In order to be able to achieve a higher speed transmission, the channel capacity C is required to be increased as far as possible. It can be seen from formula (1) that the transmission capacity C of the channel can be increased by enhancing the signal bandwidth B or the signal S. However, the signal bandwidth B is determined by the amplitude frequency characteristics of the channel and the signal S is defined by conditions such as a device and frequency spectrum compatibility. Therefore, both of them are limited to a certain range, and the range for enhancing the transmission capacity C of the xDSL that can be obtained through the above approach is restricted. However, from the point of view of the noise N, as long as the noise N is lowered, the channel capacity C of a line can also be enhanced.

Noises received by the receiving end of a transmission channel include such several main parts as a line thermal noise, an amplifier thermal noise, a surrounding electromagnetic coupling noise. The former two are also called background thermal noises. The energy of the background thermal noises is comparatively small, which is generally about −140 dBm/Hz. The surrounding electromagnetic coupling noise is a line noise caused by electromagnetic interference in the external environment. Usually, the surrounding electromagnetic coupling noise is much greater than the background thermal noises. Therefore, the control of the energy of noises is mainly the control of the energy of the surrounding electromagnetic coupling noise. In a noise pattern, the surrounding electromagnetic coupling noises mainly include an impulsive noise, a periodic noise and a continuous noise. An impulsive noise, such as the noise caused by a thunderbolt or a great surge current in a power line, has a very short duration. A periodic noise, such as the noise caused by periodic pulse interference, has a long duration and its change rule has certain periodicity. A continuous noise, such as the noise caused by a current transmitted in a power line, has a long duration and its change does not observe a regular rule.

Theoretically, if electromagnetic shielding is applied to the transmission line, the surrounding electromagnetic coupling noise can be reduced or even eliminated radically. A currently feasible method is to adopt Shielded Twist Pair (STP) as a line bearing the xDSL instead of the UTP. However, because the outer layer of the STP is coated with a metal foil so that the cost of the STP is much higher than that of the UTP and the installation is much more difficult, and this method is not adopted except in a very few applications. In the processing of the prior art, the negative influence generated by the impulsive noise is generally reduced through interleaving, trellis encoding, etc, and the influence of the noise energy of the periodic noise or continuous noise on the channel capacity can be reduced only by way of Signal to Noise Ratio (SNR) margin. The method of the SNR margin has a disadvantage that the network transmission rate is also reduced while the influence of the periodic noise or continuous noise on the channel capacity is reduced.

### SUMMARY

One embodiment provides a method for reducing a surrounding coupling noise. The method includes: receiving a signal from a receiving end of a line to be processed and obtaining a reference noise signal; determining a weight coefficient for adjusting the reference noise signal; and filtering the reference noise signal with a transfer function configured by the determined weight coefficient, superposing the filtered signal with the signal received from the receiving end of the line to be processed, and outputting the superposed signal.

Another embodiment provides a device for reducing a surrounding coupling noise. The device includes: a weight coefficient processing unit configured to receive a reference noise signal, obtain a weight coefficient according to a signal from an adder, filter the received reference noise signal with a transfer function configured by the weight coefficient, and input the filtered signal into the adder. The adder is adapted to receive a signal from a receiving end of a line to be processed, superpose the received signal from the receiving end of the line to be processed with the filtered signal from the weight coefficient processing unit, transmit the superposed signal to the weight coefficient processing unit and output the superposed signal out as an output signal of the device.

The method and the device of the embodiments can reduce the surrounding coupling noise of a line to be processed by using a correlation between surrounding noises of respective lines and using the noise signal of the reference line as the reference noise signal to cancel the noise signal of the line to be processed, so as to enhance the channel capacity of the line. The technical solutions of the embodiments are applicable to an impulsive, a periodic or a continuous surrounding coupling noise.

### BRIEF DESCRIPTIONS OF THE DRAWINGS

FIG. 1 is a schematic diagram of the connection relation of an xDSL system;

FIG. 2 is a schematic diagram showing that three lines are simultaneously influenced by an external electromagnetic interference;

FIG. 3 is a schematic diagram of a device according to one embodiment; and

FIG. 4 is a flowchart illustrating a method according to one embodiment.

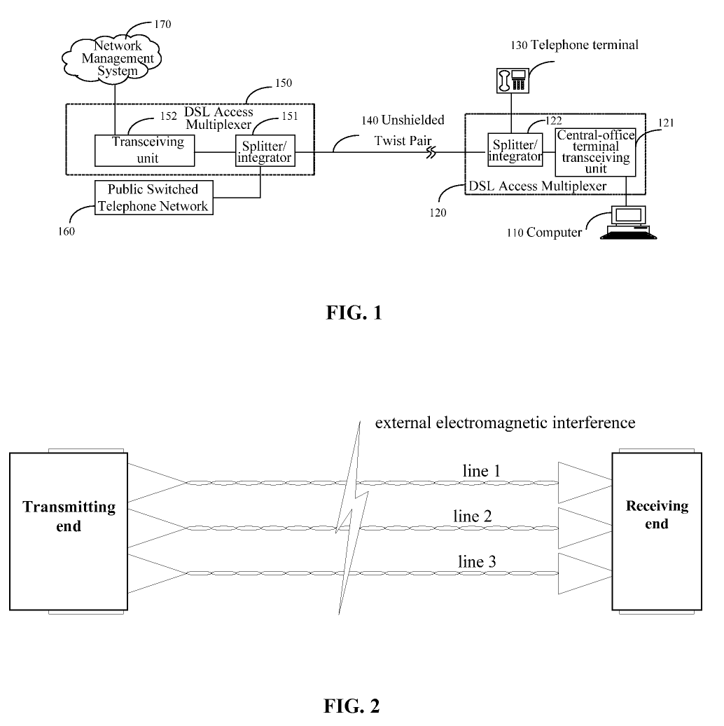

### DETAILED DESCRIPTIONS OF THE EMBODIMENTS

An electromagnetic interference from the external environment always influences a plurality of lines simultaneously, and a prominent characteristic of the surrounding electromagnetic coupling noise is that a plurality of lines are simultaneously influenced and the surrounding electromagnetic coupling noises of respective lines have a certain correlation. Therefore, theoretically, by using the correlation, the influences of the surrounding electromagnetic coupling noises on the plurality of lines can be cancelled with each other by a certain processing method, which in effect is equivalent to the reduction of the surrounding electromagnetic coupling noises.

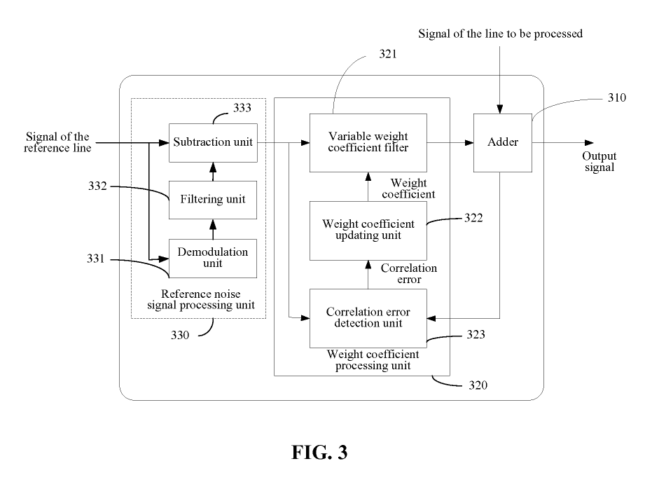

FIG. 2 is a schematic diagram showing that three lines are simultaneously influenced by an external electromagnetic interference. The pattern of the external surrounding electromagnetic interference can be impulsive, periodic or continuous, or an arbitrary superposition of the above three patterns. The noise signal is represented by Nₛ. Signals transmitted by a transmitting end of line 1, line 2 and line 3 are represented by X₁, X₂ and X₃, respectively. The receiving signals Y₁, Y₂ and Y₃ received by a receiving end are:

Y₁=H¹×X₁+H^{w1}×Nₛ+σ₁ (2)

Y₂=H²×X₂+H^{w2}×Nₛ+σ₂ (3)

Y₃=H³×X₃+H^{w3}×Nₛ+σ₃ (4)

where, H¹, H² and H³ are transfer functions of the three lines, H^{w1}, H^{w2} and H^{w3} are coupling functions of the surrounding noises of the three lines, and σ₁, σ₂ and σ₃ are background thermal noise signals of the three lines, respectively.

One embodiment provides a method for reducing surrounding coupling noise, which mainly includes.

Act 1: the reference noise signal of the external electromagnetic interference is determined.

In this embodiment, Line 1 is used as a reference line, and a total noise signal N₁ of line 1 is obtained. The noise signal is used as the reference noise signal Nᵣ:

Nᵣ=N₁=H^{w1}×Nₛ+σ₁ (5)

The reference noise signal includes the background thermal noise σ₁ and the surrounding electromagnetic coupled noise H^{w1}×Nₛ. The total noise signal N₁ of line 1 can be obtained by using the following two methods.

Method 1: The transmitting end of line 1 does not transmit a service signal, and then the signal received by the receiving end of line 1 is the noise signal N₁ of line 1.

Method 2: signal X₁ transmitted through line 1 is obtained by demodulation processing, while H¹ can be obtained through a parameter reported by a transceiver and thus can be used as a known parameter. The total noise signal N₁ of line 1 can be obtained by subtracting H¹×X₁ from the received signal Y₁.

Act 2: an opposite number ηᵢ of a ratio of the surrounding noise coupling function of another line and that of the reference line is determined, where i represents the number of the line. For example, the opposite number η₂ of the ratio of the surrounding noise coupling function of line 2 and that of the reference line is:

η₂=−H^{w2}/H^{w1} (6)

Generally, the surrounding noise coupling functions of the respective lines approximate each other, thus ηᵢ≈−1.

Act 3: the external surrounding electromagnetic coupling noise of another line is cancelled with the reference noise signal.

The execution process is as follows. The reference noise signal Nᵣ is multiplied by ηᵢ, the obtained result is superposed with a signal Yᵢ received by the receiving end of another line, and the superposed signal Yᵢ′ is used as the signal of the line after cancellation. Still taking line 2 as an example, the signal of line 2 after counteraction is represented by Y₂′, then

$$\begin{matrix}{Y}_{2}^{′} = {Y}_{2} + {η}_{2} \times {N}_{r} \\ = {H}^{2} \times {X}_{2} + {H}^{w 2} \times {N}_{s} + {σ}_{2} - \frac{{H}^{w 2}}{{H}^{w 1}} \times ( {H}^{w 1} \times {N}_{s} + {σ}_{1} ) \\ = {H}^{2} \times {X}_{2} + ( {σ}_{2} - \frac{{H}^{w 2}}{{H}^{w 1}} \times {σ}_{1} )\end{matrix} \qquad ( 7 )$$

It can be seen from formula (3) and (7) that, before the cancellation, the noise of line 2 is N₂=H^{w2}×Nₛ+σ₂, while after the cancellation, the noise of line 2 is

$${N}_{2}^{′} = {σ}_{2} - \frac{{H}^{w 2}}{{H}^{w 1}} \times {σ}_{1} .$$

The magnitude of N₂′ is substantially equal to that of the background thermal noise σ₂. Therefore, through the cancellation, the surrounding coupling noise of line 2 is greatly reduced.

The surrounding coupling noise of line 3 can be canceled by using an approach similar to the above.

What has been described above is a theoretically ideal case. In fact, a surrounding noise coupling function is a function that varies along with a noise source signal Nₛ, and the variation of the noise source signal Nₛ is usually very complicated and unpredictable, so it is difficult to obtain the exact value of ηᵢ.

Based on the above reasons, in the device according to one embodiment, η is adaptively adjusted by using an adaptive filter so as to achieve the optimal effect of canceling the surrounding coupling noise.

The device according to the embodiment may be located in the DSLAM at the receiving end of a multi-user line, and specifically in the splitter/integrator in the DSLAM.

Referring to FIG. 3, the device includes an adder 310 and a weight coefficient processing unit 320. The adder 310 is adapted to receive the signal Yᵢ from the receiving end of the line to be processed and superpose the received signal of the line with a signal from the weight coefficient processing unit 320. The superposed signal is used as the output signal Yᵢ′ after cancellation and is sent to the weight coefficient processing unit 320.

The weight coefficient processing unit 320 is adapted to receive the reference noise signal Nᵣ from the reference line, i.e. a noise signal of the reference line; calculate to obtain a weight coefficient ωᵢ based on the signal Yᵢ′ from the adder 310 and the reference noise signal Nᵣ; filter the received reference noise signal with the transfer function configured by the weight coefficient ωᵢ, which is equivalent to multiplying the weight coefficient ωᵢ by respective delay points of the reference noise signal Nᵣ and accumulating the products; and input the filtered signal into the adder 310.

The weight coefficient processing unit 320 may further include a variable weight coefficient filter 321, a weight coefficient updating unit 322 and a correlation error detection unit 323.

The variable weight coefficient filter 321 is adapted to receive the reference noise signal Nᵣ of the reference line and the weight coefficient ωᵢ from the weight coefficient updating unit 322, filter the received reference noise signal with the transfer function configured by the weight coefficient ωᵢ, and input the filtered signal to the adder 310.

The weight coefficient updating unit 322 is adapted to receive a correlation error δᵢ from the correlation error detection unit 323, obtain the weight coefficient ωᵢ based on δᵢ, and send the obtained ωᵢ to the variable weight coefficient filter 321. The ωᵢ is a transfer function of the variable weight coefficient filter 321 and approaches a target value which is an opposite number of the ratio of the noise coupling function H^{wi} of the present line and the noise coupling function H^{w1} of the reference line, i.e. ωᵢ→ηᵢ=−H^{wi}/H^{w1}. The algorithm from which the weight coefficient ωᵢ is obtained can be a Least Mean Square (LMS) algorithm, Recursive Least square (RLS) algorithm, some other adaptive filtering algorithms or a certain improved algorithm based on these algorithms. The embodiment of the disclosure is not limited to the specific algorithm adopted.

The correlation error detection unit 323 is adapted to receive the reference noise signal Nᵣ of the reference line and the signal Yⁱ′ from the adder 310, calculate the correlation error δᵢ based on the received Nᵣ and Yᵢ′, and input δᵢ into the weight coefficient updating unit 322.

If the reference noise signal is obtained by using above mentioned method 2, a reference noise signal processing unit 330 is needed to receive the signal from the reference line and output the reference noise signal after being processed according to method 2 to the weight coefficient processing unit 320. If the reference noise signal is obtained by using method 1, no such a reference noise signal processing unit is needed.

The reference noise signal processing unit 330 includes a demodulation unit 331, a filtering unit 332 and a subtraction unit 333. The demodulation unit 331 is adapted to receive the signal from the receiving end of the reference line, demodulate the received signal to obtain the signal sent by the transmitting end of the reference line, and output the obtained signal of the transmitting end to the filtering unit 332.

The filtering unit 332 is adapted to filter the signal from the demodulation unit 332 according to the advance-obtained transfer function of the reference line and output the filtered signal to the subtraction unit 333. The transfer function of the reference line can be preset.

The subtraction unit 333 is adapted to subtract the signal from the filtering unit 332 from the signal from the receiving end of the reference line. The signal obtained after the subtraction is output to the weight coefficient processing unit 320 as the reference noise signal.

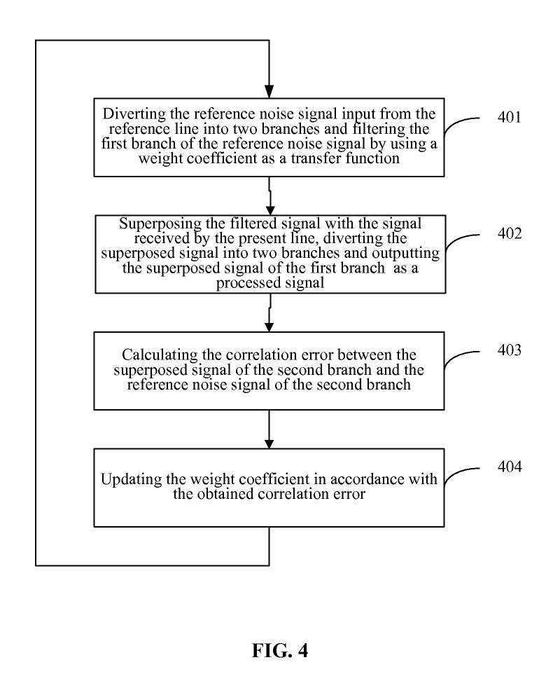

FIG. 4 is a flowchart illustrating a method for canceling coupling noise according to one embodiment. The method includes:

Act 401, the reference noise signal Nᵣ input from the reference line is diverted into two branches, the first branch of the reference noise signal is filtered with the transfer function configured by the weight coefficient ωᵢ. Nᵣ is the noise signal of the reference line. The initial values of ωᵢ can be set according to the method for using an existing adaptive filter, for example, all of them are set to be 0.1.

Act 402, the filtered result

$${\sum }_{i = 0}^{n} {w}_{i} \times {N}_{r} ( t - i )$$

is superposed with the signal Yᵢ received by the present line. The superposed signal is diverted into two branches. The first branch of the superposed signal is output as the processed signal Yᵢ′.

Act 403, the correlation error δᵢ between the second branch of the superposed signal and the second branch of the reference noise signal is calculated.

Act 404, the weight coefficient ωᵢ is updated according to the obtained correlation error δᵢ. The algorithm adopted in this Act can be, but is not limit to LMS, RLS, or an improved algorithm based on these two algorithms.

After performing Act 404, the process returns to and continuously performs step 401.

The above Acts 401 to 404 are a working cycle. The weight coefficient ωᵢ used in Act 401 may be the weight coefficient obtained in Act 404 of the previous cycle.

By using this kind of method for adaptively adjusting the weight coefficient, even if the weight coefficient ωᵢ is greatly different from its target value ηᵢ sometimes, for example, the surrounding noise coupling functions H^{wi} of respective lines vary due to the variation of the external electromagnetic interference while the weight coefficient ωᵢ is not adjusted immediately along with it, the weight coefficient, ωᵢ can be adaptively converged to the ideal target value ηᵢ by using several cycles of the above mentioned Acts 401 to 404, and thus influences of the large part of the surrounding coupling noises on the channel capacity can be substantially eliminated by using the method of canceling the surrounding coupling noise according to the embodiments.

While the above embodiments is applied to a multi-user line of the xDSL system, those skilled in the art should recognize that as long as it is the case where the same device receives and processes signals transmitted from a plurality of lines simultaneously, the embodiments can be applied to reduce the coupling noises. For example, the method of the embodiments can be used to reduce the coupling noises of a plurality of lines accessing to a router device in an Ethernet.

What has been described above are only exemplary embodiments, and are not used to limit the present invention. Any modifications, equivalent alternations and improvements made within the spirit and principle of the present invention shall fall into the protection scope of the present invention.

What is claimed is:

1. A method for reducing surrounding coupling noise, comprising:
determining a reference noise signal, the reference noise signal being a total noise signal in a first line;
filtering the reference noise signal by using a weight coefficient to obtain a filtered signal; and
superposing the filtered signal and a signal received from a receiving end of a second line to obtain a superposed signal.

2. The method of claim 1, wherein the weight coefficient is a preset value.

3. The method of claim 1, comprising:
obtaining the weight coefficient by calculating the reference noise signal and the superposed signal.

4. The method of claim 3, comprising:
obtaining a correlation error by calculating the reference noise signal and the superposed signal; and
obtaining the weight coefficient according to the correlation error.

5. The method of claim 1, obtaining the weight coefficient by one of a least mean square (LMS) algorithm or a recursive least square (RLS) algorithm.

6. The method of claim 1, wherein the total noise signal comprises a background thermal noise and a surrounding electromagnetic coupling noise.

7. The method of claim 1, wherein the weight coefficient is an opposite number of a ratio of a surrounding noise coupling function of the second line and a surrounding noise coupling function of the first line.

8. A device for reducing surrounding coupling noise, comprising a variable weight coefficient filter and an adder, wherein
the variable weight coefficient filter is adapted to receive a reference noise signal, filter the reference noise signal and send the filtered signal to the adder, the reference noise signal is a total noise signal of a first line;
the adder is adapted to receive a signal from a receiving end of a second line, and superpose the filtered signal and the signal received from the receiving end of the second line to obtain a superposed signal.

9. The device of claim 8, wherein the weight coefficient is a preset value.

10. The device of claim 8, wherein the device further comprises a weight coefficient updating unit adapted to receive the reference noise signal and the superposed signal, obtain the weight coefficient by calculating the reference noise signal and the superposed signal and send the weight coefficient to the variable weight coefficient filter.

11. The device of claim 8, wherein the device further comprises a correlation error detecting unit and a weight coefficient updating unit,
the correlation error detecting unit is adapted to receive the reference noise signal and the superposed signal, obtain a correlation error by calculating the reference noise signal and the superposed signal and send the correlation error to the weight coefficient updating unit;
the weight coefficient updating unit is adapted to receive the correlation error, obtain the weight coefficient according to the correlation error and send the weight coefficient to the variable weight coefficient filter.

12. The device of claim 10, wherein the weight coefficient is substantially the same as an opposite number of a ratio of a surrounding noise coupling function of the second line and a surrounding noise coupling function of the first line.

13. The device of claim 10, wherein the weight coefficient is obtained by using one of a least mean square (LMS) algorithm or a recursive least square (RLS) algorithm.

14. The device of claim 8, wherein the device further comprises a demodulation unit, a filtering unit and a subtraction unit,
the demodulation unit is adapted to receive a signal received from a receiving end of the first line, demodulate the signal received from the receiving end of the first line to obtain a signal sent from a transmitting end of the first line, and send the signal sent from the transmitting end of the first line to the filter unit;
the filter unit is adapted to filter the signal from the demodulation unit and send the filtered signal to the subtraction unit;
the subtraction unit is adapted to received the signal received from the receiving end of the first line and the filtered signal, obtain the reference noise signal by subtract the filtered signal received from filter unit from the signal received from the receiving end of the first line.

15. A network device, comprising a device that reduces surrounding coupling noise, wherein the device that reduces surrounding coupling noise is adapted to:
receive a reference noise signal and filter the reference noise signal, the reference noise signal is a total noise signal of a first line; and
receive a signal from a receiving end of a second line, and superpose the filtered signal and the signal received from the receiving end of the second line to obtain a superposed signal.

16. The network device of claim 15, wherein the network device is a digital subscriber line access multiplexer, and the network device further comprises a splitter adapted to receive the superposed signal from the device that reduces surrounding noise and split the superposed signal into a digital subscriber line signal and a plain old telephone service signal.

17. The network device of claim 15, wherein the network device comprises a router in an Ethernet.

18. The network device of claim 15, wherein the device that reduces surrounding coupling noise comprises a variable weight coefficient filter and an adder,
the variable weight coefficient filter is adapted to receive the reference noise signal, filter the reference noise signal and send the filtered signal to the adder;
the adder is adapted to receive the signal from the receiving end of the second line, and superpose the filtered signal and the signal received from the receiving end of the second line to obtain the superposed signal.

19. The network device of claim 18, wherein the device that reduces surrounding coupling noise further comprises a correlation error detecting unit and a weight coefficient updating unit,
the correlation error detecting unit is adapted to receive the reference noise signal and the superposed signal, obtain a correlation error by calculating the reference noise signal and the superposed signal and send the correlation error to the weight coefficient updating unit;
the weight coefficient updating unit is adapted to receive the correlation error, obtain the weight coefficient according to the correlation error and send the weight coefficient to the variable weight coefficient filter.

20. A splitter for a digital subscriber line, comprising a splitter unit and a device that reduces surrounding coupling noise, wherein the device that reduces surrounding coupling noise comprises a variable weight coefficient filter and an adder,
the variable weight coefficient filter is adapted to receive a reference noise signal, filter the reference noise signal and send the filtered signal to the adder, the reference noise signal is a total noise signal of a first line;
the adder is adapted to receive a signal from a receiving end of a second line, and superpose the filtered signal and the signal received from the receiving end of the second line to obtain a superposed signal;
the splitter unit is adapted to receive the superposed signal from the device for reducing surrounding noise and split the superposed signal into a digital subscriber line signal and a plain old telephone service signal.

21. A computer readable media, comprising logic encoded in the computer readable media, the logic when executed operable to:
determine a reference noise signal, the reference noise signal being a total noise signal in a first line;
filter the reference noise signal by using a weight coefficient to obtain a filtered signal; and
superpose the filtered signal and a signal received from a receiving end of a second line to obtain a superposed signal.
